(19) United States
(12) Patent Application Publication
(10) Pub. No.: US 2008/0160785 A1
(43) Pub. Date: Jul. 3, 2008

(54) Method Of Forming Oxide Layer In Semiconductor Device

(75) Inventors: Wan Sup SHIN, Seoul (KR); Kwang Chul JOO, Kyungki-Do (KR); Kwang Seok JEON, Yongin-Si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyeonggi-do (KR)

(21) Appl. No.: 11/759,670

(22) Filed: Jun. 7, 2007

(30) Foreign Application Priority Data
Dec. 28, 2006 (KR) 10-2006-136221

(51) Int. Cl. H01L 21/469

(52) U.S. Cl. 438/787; 257/E21.487

(57) ABSTRACT

A method of forming an oxide layer in a semiconductor device comprising the step of loading a semiconductor substrate in a chamber, optionally increasing a temperature of an interior of the chamber, performing the first oxidation process in the chamber under the atmosphere of ozone to form an oxide layer on the semiconductor substrate, and lowering a temperature of an interior of the chamber.

### CROSS-REFERENCE TO RELATED APPLICATION

The priority of Korean Patent Application No. 10-2006-136221, filed on Dec. 28, 2006, the contents of which are incorporated herein by reference in their entirety, is claimed.

### BACKGROUND OF THE INVENTION

1. Field of the Invention

The present invention relates to a method of forming an oxide layer in a semiconductor device and more particularly, to a method of forming an oxide layer in a semiconductor device utilizing ozone gas.

2. Related Technology

In a process for manufacturing a semiconductor device, an oxide layer may be used for different purposes. For example, the oxide layer is employed as a gate insulating layer formed below a gate, an oxide layer formed as a portion of a dielectric layer, a protective layer for compensating an etching damage of a semiconductor substrate after forming a trench on the semiconductor substrate, and a protective layer formed on a side wall of the gate.

On the other hand, as semiconductor devices become more highly-integrated, a dielectric layer between a floating gate and a control gate becomes thinner in order to secure a coupling ratio. However, as the thickness of the dielectric layer is reduced, the quality of the oxide layer deteriorates.

A conventional process for forming an oxide layer is performed under an atmosphere of 02 gas or H₂O gas. However, in a case where the oxide layer is formed on the semiconductor substrate through such a process, a trap site such as a dangling bond may be formed on an interface between the semiconductor substrate made of silicon and silicon oxide (SiO₂). If the trap site is formed, the off current of the gate is increased and the on/off current ratio may be reduced.

### SUMMARY OF THE INVENTION

In the invention, an oxidation process is performed under an atmosphere of ozone for forming an oxide layer so that an electrical characteristic of the semiconductor device can be enhanced.

The invention relates to a method of forming an oxide layer in a semiconductor device. In the method for forming the oxide layer according to the invention, a semiconductor substrate is loaded in a chamber. The temperature of the interior of the chamber is optionally increased. A first oxidation process is performed in the chamber under an atmosphere of ozone at a sufficiently high temperature to form an oxide layer on the semiconductor substrate. The temperature of an interior of the chamber is then lowered.

A furnace is preferably utilized as the chamber, ozone supplied in the first oxidation process preferably has a concentration of 10 mg/cm³ to 500 mg/cm³, the first oxidation process is preferably performed at a normal(i.e. ambient) temperature to 1,000° C. and preferably a pressure of 0.1 Torr to 760 Torr.

A second oxidation process is preferably additionally carried out prior to the first oxidation process, and the second oxidation process preferably utilizes additionally one of O₂ gas and H₂O gas or a mixture thereof.

O₂ gas is preferably introduced at a flow rate of 1l/minute to 50l/minute. The second oxidation process preferably utilizing H₂O gas is preferably performed by a wet oxidation method employing a torch. Also, the second oxidation process preferably utilizing H₂O gas is preferably performed by an extreme decompression radical oxidation method employing a radical reaction or by a wet vapor generating (WVG) method in which H₂O is evaporated.

### BRIEF DESCRIPTION OF THE DRAWINGS

The above and other features and advantages of the invention will become readily apparent by reference to the following detailed description when considered in conjunction with the accompanying drawings wherein:

FIG. 1 is a view illustrating a method of forming an oxide layer in a semiconductor device according to the embodiment of the invention;

FIG. 2 is a view illustrating a method of forming an oxide layer in a semiconductor device according to another embodiment of the invention; and

FIG. 3A to FIG. 3F are views for illustrating one embodiment of a method of manufacturing the semiconductor device to which the invention is applied.

### DESCRIPTION OF SPECIFIC EMBODIMENTS

Hereinafter, the preferred embodiments of the invention will be explained in more detail with reference to the accompanying drawings. However, the embodiments of the invention may be variously modified, and the scope of the invention is not limited to the embodiments described below. The embodiment is provided for illustrating more completely the invention to those skilled in the art.

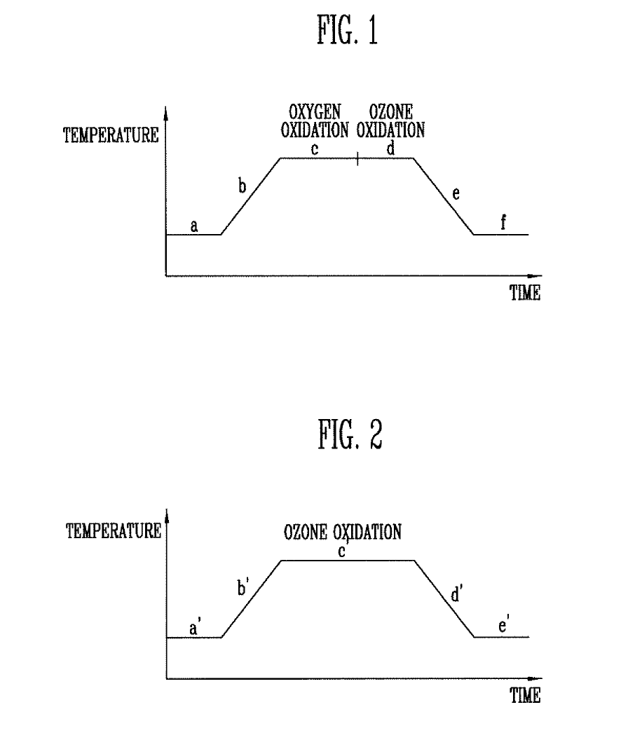

FIG. 1 is a view illustrating a method of forming an oxide layer in a semiconductor device according to the embodiment of the invention. The method of forming an oxide layer utilizing ozone (03) gas proposed in the invention can be performed together with an oxide layer forming method performed under an atmosphere of oxygen, and only ozone gas can be used in the method of forming an oxide layer. In the above methods, FIG. 1 shows the method in which an oxidation process under an atmosphere of oxygen and an oxidation process utilizing ozone gas are performed to form an oxide layer.

The oxide layer is formed by performing the oxidation process under an atmosphere of oxygen and the oxidation process under an atmosphere of ozone, the oxidation process utilizes mainly O₂ gas or H₂O gas and is performed at a temperature of 700° C. to 1,000° C. In the “a” section, the semiconductor substrate on which the oxide layer will be formed is loaded in a chamber (for example, a furnace) in which the oxidation process can be performed. In the “b” section (which is a ramp up section), the temperature is increased up to a temperature at which the oxidation process is performed. In the “c” section, the temperature required for performing an oxidation process is reached, and O₂ gas or H₂O gas is introduced into the chamber to perform the first oxidation process. A first oxide layer is formed by the first oxidation process. The first oxidation process may be performed by a radical oxidation method, for example. If the first oxide layer is an oxide layer formed on the semiconductor substrate, the first oxide layer is formed of a silicon oxide (SiO₂) layer. On the other hand, once the oxide layer is formed through the oxidation process under an atmosphere of oxygen, a dangling bond is generated on an interface between the silicon substrate made of silicon (Si) and the first oxide layer (SiO₂), an electrical characteristic can be deteriorated by the dangling bond. Accordingly, the thinner a thickness of the layer is, the more deteriorated a break down voltage characteristic and the like can be.

In the “d” section, accordingly, the second oxidation process as the subsequent process is performed under an atmosphere of ozone (O₃) gas. When ozone gas is dissolved by the energy, ozone gas is made to be in a radical state in which ozone gas is chemically unstable, and generates oxygen radical and OH radical so that ozone gas has a large a large reactivity with silicon. Due to such radical reaction, ozone gas is bonded to silicon dangling bond existed on an interface between the semiconductor substrate and the silicon oxide (SiO₂) layer, and so the trap site can be removed. Also, since the radical may be formed at a low temperature so that the second oxidation process can be performed at a low temperature, it is possible to form a thin oxide layer which does not have a transition layer and has a thickness of several angstroms. In addition, since the oxygen radical has a large reactivity with organic material, it is easy to remove carbon-based residue or molecular carbon (AMC) produced in a subsequent etching process.

In the “e” section, the temperature falls, and the oxidation forming process is completed in the “f” section if a temperature has fallen.

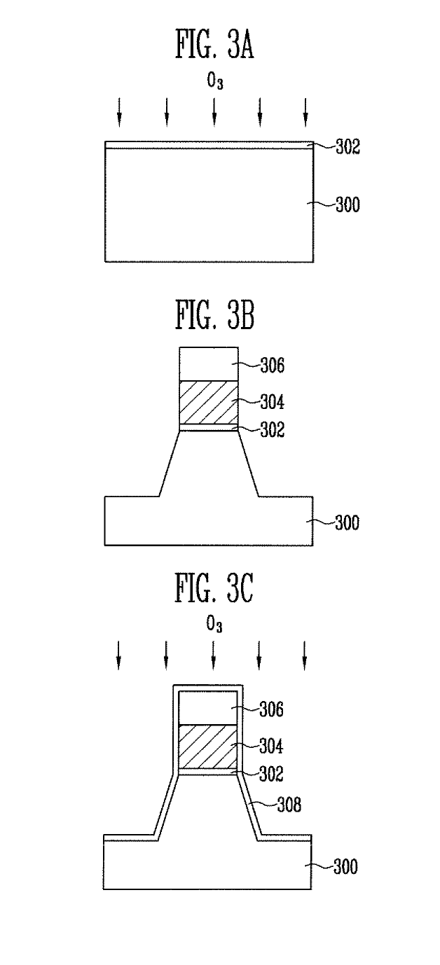

FIG. 2 is a view illustrating a method of forming the oxide layer in the semiconductor device according to another embodiment of the invention. In the “a′” section, the semiconductor substrate on which the oxide layer will be formed is loaded in a furnace. In the “b′” section, which is a ramp up section, the temperature is increased up to a temperature at which the oxidation process is performed. In the “c′” section, the oxide layer is formed by utilizing ozone (O₃) gas. When ozone gas is dissolved by the energy, ozone gas is made to be in a radical state in which ozone gas is chemically unstable, and generates oxygen radical and OH radical so that ozone gas has a large a large reactivity with silicon. Due to such radical reaction, ozone gas is bonded to silicon dangling bond existed on an interface between the semiconductor substrate and the silicon oxide (SiO₂) layer, and so the trap site can be removed. That is, the oxide layer is formed through only the oxidation process performed in an atmosphere of ozone (O₃) without performing the first oxidation process illustrated with reference to FIG. 1. Also, since the radical may be formed at a low temperature so that the second oxidation process can be performed at a low temperature, it is possible to form a thin oxide layer which does not have a transition layer and has a thickness of several angstroms. In addition, since the oxygen radical has a large reactivity with organic material, it is easy to remove carbon-based residue or molecular carbon (AMC) produced in a subsequent etching process.

In the “d′” section, the temperature falls, and the oxidation forming process is completed in the “e′” section.

Next, a method of forming the oxide layer utilizing ozone (O₃) gas applied to the method of manufacturing the semiconductor device is described.

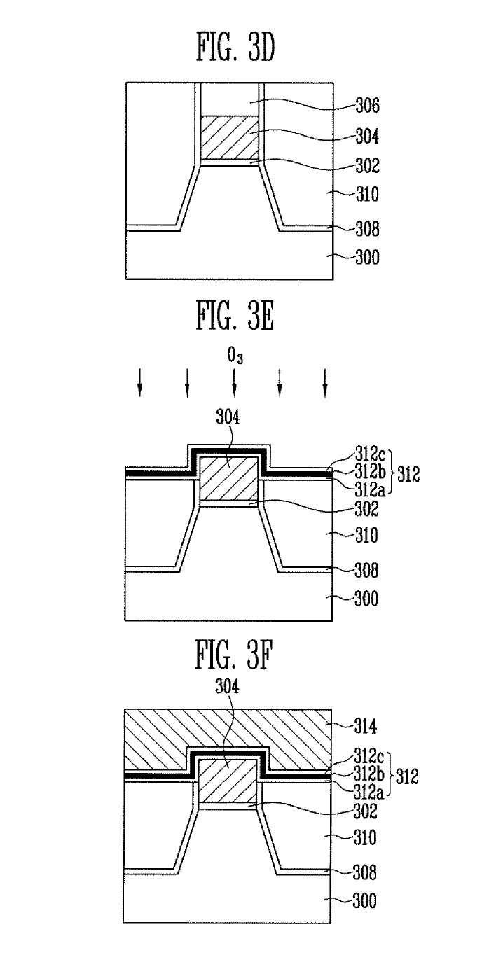

FIG. 3A to FIG. 3F are view for illustrating one embodiment of a method of manufacturing the semiconductor device to which the invention is applied.

Referring to FIG. 3A, a gate insulating layer 302 is formed on a semiconductor substrate 300. The gate insulating layer 302 is formed by employing ozone (O₃) gas. The gate insulating layer 302 has a reactivity with the semiconductor substrate 300 which is higher than that of an oxide layer formed by employing oxygen (O₂) gas.

Referring to FIG. 3B, a first conductive layer 304 for the floating gate and a hard mask layer 306 are formed on the gate insulating layer 302. The first conductive layer 304 and the gate insulating layer 302 are patterned along patterns of the hard mask layer 306 through the etching process to form a trench on the semiconductor substrate 300.

Referring to FIG. 3C, in order to compensate for etching damage generated on an inner surface of the trench when the trench is formed, the oxidation is performed to form a protective layer 308. The protective layer 308 is formed through the oxidation process utilizing ozone (O₃) gas. The oxidation process is performed under the condition of a concentration of ozone (O₃) gas of 10 mg/cm₃ to 500 mg/cm₃, and a temperature of a normal temperature to 1,000° C. and a pressure of 0.1 Torr to 760 Torr. At this time, in order to promote an oxidation, the first oxidation process as illustrate in the above description regarding FIG. 1 may be additionally performed before the oxidation process utilizing ozone (O₃) gas. In this case, when the first oxidation process is performed, O₂ gas is introduced at a flow rate of 1l/minute to 50l/minute. Also, if H₂O gas is utilized in the first oxidation process, the first oxidation process may be performed by any one of wet oxidation method employing a torch, an extreme decompression radical oxidation method employing a radical reaction and a wet vapor generating (WVG) method in which H₂O is evaporated and then utilized.

Since the protective layer 308 formed by ozone (O₃) has a lattice structure which is the same as a structure of silicon, the bonding between the protective layer and the semiconductor substrate 300 can be improved. In addition, the protective layer can reduce a stress of the semiconductor substrate 300 to inhibit a generation of the trap site.

Referring to FIG. 3D, an insulating layer is formed such that all the hard mask layer 306 is covered with the insulating layer, and a chemical mechanical polishing process is then carried out such that the hard mask layer 306 is exposed, and so an isolation structure 310 is formed.

Referring to FIG. 3E, the hard mask layer 306 is removed such that the first insulating layer is 304 is exposed, and a portion of the isolation structure 310 is removed so as to adjust an effective field oxide height (EFH). At this time, a portion of the protective layer 108 is simultaneously removed. A dielectric layer 312 is formed on the isolation structure 310 and the first conductive layer 304. The dielectric layer 312 has a stack structure formed of a first oxide layer 312a, a nitride layer 312b, and a second oxide layer 312c. At this time, the first and second oxide layers 312a and 312c may be formed through the oxidation process utilizing ozone (O₃) gas.

Referring to FIG. 3F a second conductive layer 314 for the control gate is formed on the dielectric layer 312. Subsequently, a gate patterning process is performed, a subsequent process is then carried out.

Although embodiments have been described with reference to a number of illustrative embodiments thereof, numerous modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

The invention can achieve at least the following advantages.

First, a thickness of the oxide layer can be easily controlled.

Second, a generation of the trap site is inhibited to prevent the semiconductor device from being electrically deteriorated.

Third, a coupling ratio can be secured.

What is claimed is:

1. A method of forming an oxide layer in a semiconductor device, comprising the step of;
loading a semiconductor substrate in a chamber;
optionally increasing a temperature of an interior of the chamber in a temperature sufficiently high to perform an oxidation process;
performing a first oxidation process in the chamber under an atmosphere of ozone and a temperature sufficiently high to form an oxide layer on the semiconductor substrate; and
lowering the temperature of the interior of the chamber.

2. The method according to claim 1, wherein the chamber is a furnace.

3. The method according to claim 1, comprising performing ozone in the first oxidation process at a concentration of 10 mg/cm³ to 500 mg/cm³.

4. The method according to claim 1, comprising performing the first oxidation process at room temperature to 1,000° C. and at a pressure of 0.1 Torr to 760 Torr.

5. The method according to claim 1, further comprising the step of performing the second oxidation process carried out prior to the first oxidation process.

6. The method according to claim 5, wherein the second oxidation process utilizes at least one of O₂ gas and H₂O gas.

7. The method according to claim 6, wherein O₂ gas utilized in the second oxidation process is introduced at a flow rate of 1l/minute to 50l/minute.

8. The method according to claim 6, comprising performing the second oxidation process utilizing H₂O gas by a wet oxidation method employing a torch.

9. The method according to claim 6, comprising performing the second oxidation process utilizing H₂O gas by an extreme decompression radical oxidation method employing a radical reaction.

10. The method according to claim 1, comprising performing the second oxidation process utilizing H₂O gas by a wet vapor generating (WVG) method in which H₂O is evaporated and then used.
